(19) United States
(12) Patent Application Publication
(10) Pub. No.: US 2008/0113464 A1
(43) Pub. Date: May 15, 2008

(54) Asymmetric chalcogenide device

(76) Inventor: Semyon D. Savransky, Newark, CA (US)

Correspondence Address: TROP PRUNER & HU, PC, 1616 S. VOSS ROAD, SUITE 750, HOUSTON, TX, 77057-2631, US

(21) Appl. No.: 11/545,234

(22) Filed: Oct. 10, 2006

(51) Int. Cl. H01L 21/00; H01L 21/06

(52) U.S. Cl. 438/48; 438/95; 438/102

(57) ABSTRACT

A semiconductor device with S-type negative differential resistance (e.g., phase change memory or threshold switch) may be formed with an asymmetric i-v curve. The asymmetric nature may be achieved by using a lower electrode formed of a semiconductor material such as doped amorphous or polycrystalline semiconductor. The resulting device may have a threshold voltage and leakage current that depend on the polarity of the applied electrical signal. In some embodiments, an ovonic threshold switch with an asymmetric i-v curve may be combined with an ovonic memory cell with an asymmetric i-v curve.

### BACKGROUND

This relates generally to semiconductor devices with S-type negative differential resistance, such as phase change memories or threshold switches.

Phase change memory devices use phase change materials, i.e., materials that may be electrically switched between a generally amorphous and a generally crystalline state, for electronic memory application. One type of memory element utilizes a phase change material that may be, in one application, electrically switched between a structural state of generally amorphous and generally crystalline local order or between different detectable states of local order across the entire spectrum between completely amorphous and completely crystalline states. The state of the phase change materials is also non-volatile in that, when set in either a crystalline, semi-crystalline, amorphous, or semi-amorphous state representing a resistance value, that value is retained until changed by another programming event, as that value represents a phase or physical state of the material (e.g., crystalline or amorphous). The state is unaffected by removing electrical power.

### BRIEF DESCRIPTION OF THE DRAWINGS

FIG. 1 is an enlarged, schematic, cross-sectional view of one embodiment of the present invention;

FIG. 2 is a hypothetical graph of current versus voltage for one embodiment of the present invention;

FIG. 3 is a graph of asymmetry coefficient versus resistivity of polysilicon in accordance with one embodiment of the present invention; and

FIG. 4 is a system depiction for one embodiment.

### DETAILED DESCRIPTION

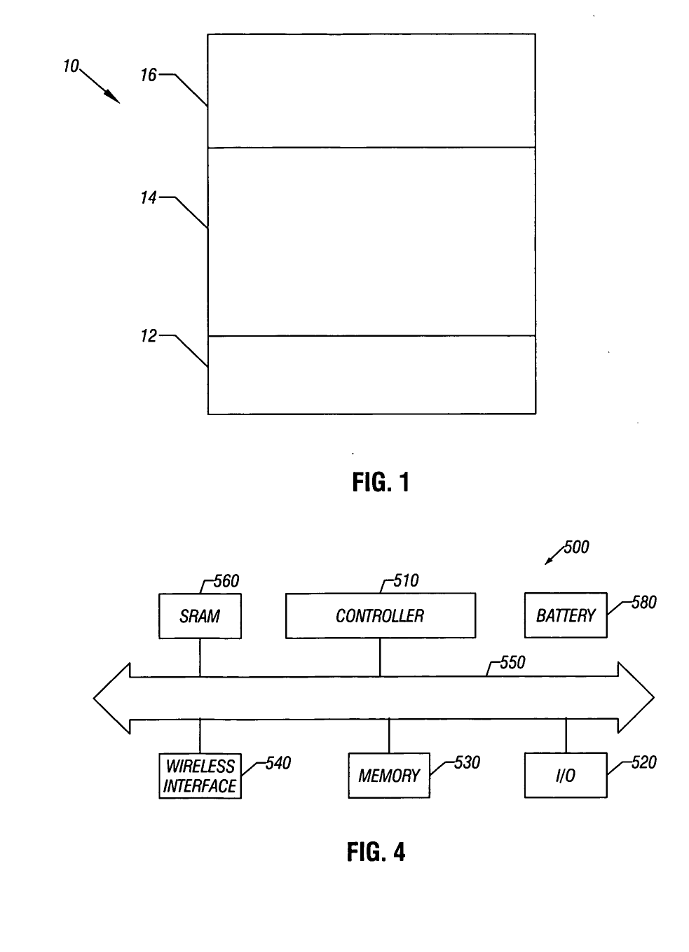

Referring to FIG. 1, in accordance with some embodiments of the present invention, a phase change memory made with a chalcogenide alloy may have bistable asymmetric current versus voltage (i-v) characteristics. By “asymmetric,” it is intended to indicate that the curves are not symmetrical about the zero voltage axis or the zero current axis.

By “bistable,” it is intended to indicate that the both low resistivity and high resistivity branches of i-v characteristics exist without additional energy applied to the device.

An asymmetric phase change memory cell has a threshold voltage and leakage current that depend on the polarity of the applied electrical signals. Conventional phase change memory cells with symmetric current-voltage or i-v curves negatively affect the read window of memory devices formed from these cells.

Referring to FIG. 1, in accordance with some embodiments of the present invention, a threshold switch with a chalcogenide alloy may have monostable asymmetric current versus voltage (i-v) characteristics. By “asymmetric,” it is intended to indicate that the curves are not symmetrical about the zero voltage axis or the zero current axis.

By “monostable,” it is intended to indicate that the both low resistivity and branch of i-v characteristics exist only when an additional energy applied to the device.

An asymmetric threshold switch cell has a threshold voltage and leakage current that depends on the polarity of the applied electrical signals. Conventional threshold switch cells with symmetric current-voltage or i-v curves negatively affect the usage of threshold switch in some electrical circles.

In some embodiments of the present invention, the asymmetric i-v curves may be provided for either ovonic threshold switches or ovonic memory cells or both. Thus, in some embodiments, both an ovonic threshold switch and an ovonic memory cell may be provided and one or both of these may have asymmetric i-v curves.

As shown in FIG. 1, the phase change memory cell 10 includes a semiconductor electrode 12. Over the electrode 12 is an active chalcogenide material 14. Thereover, an electrode 16 may be formed which is made of any conductive material. For example, it may be made of a metal, doped amorphous or polycrystalline semiconductor, such as silicon, or carbon. Suitable metals include molybdenum or titanium aluminum nitride, to mention two examples.

The active chalcogenide material 14 may be any conventional chalcogenide material used in phase change memories, including one that is an alloy of germanium, antimony, and tellurium and one that is used in threshold switches, including one that an alloy of gallium, silicon, tellurium, arsenic, and germanium, to mention two examples.

The lower or upper semiconductor electrode 12 or 16 may be formed of doped amorphous or polycrystalline semiconductor. This may be an n-type or p-type doped polysilicon or doped amorphous germanium, or doped amorphous silicon with hydrogen bonds, or doped amorphous carbon, or polycrystalline Tl—Te, or polycrystalline germanium and tellurium or polycrystalline zinc, tellurium, and copper alloy. Advantageously, the electrodes 12 and 16 have a relatively small resistivity.

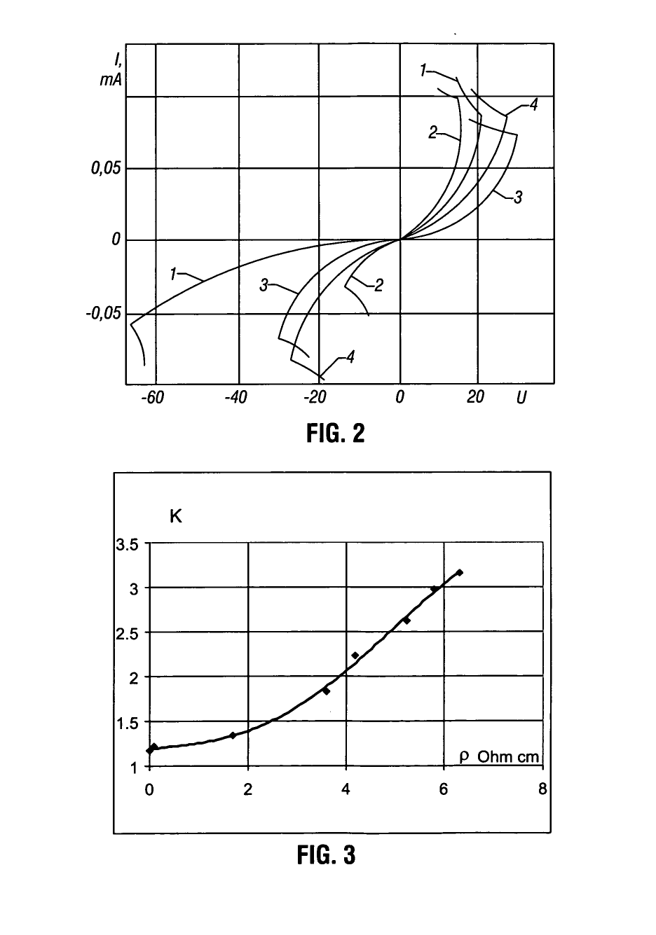

Referring to FIG. 2, with an upper electrode 16 made of molybdenum or carbon, the effect on i-v curve asymmetry is shown for different lower electrode 12 compositions where the chalcogenide material 14 is Ga₁₂Ge_{6.5}Si_{6.5}As₂₅Te₅₀. The i-v curves 1 and 2 are formed using p-type doped polysilicon as a lower electrode 12 and a metal as the upper electrode 16. The resistivity of the silicon lower electrode 12 is about 10 Ohmcentimeters for curve 1 in the case of i-v curve 1 and 0.1 Ohmcentimeters in the case of i-v curve 2. The i-v curve 3 is achieved with an n-type doped silicon lower electrode 12 having a resistivity of 0.1 Ohmcentimeter. The i-v curve 4 uses a metal for both electrodes. I-v curve 4 is provided for comparison purposes and may be considered a symmetrical i-v curve. Likewise, i-v curve 3 is only slightly asymmetrical, while curve 2 is more asymmetrical and curve 1 is highly asymmetrical.

The doped amorphous or polycrystalline semiconductor used for the semiconductor electrode 12 or 16 or one of them can have n-type or p-type conductivity and can be obtained in a thin film. It may be applied onto an alloy of chalcogenide material i-v using radio frequency sputtering. The electrodes 12 and 16 and active chalcogenide material 14 may have direct electrical contact with one another. However, an optional insulator (not shown) may surround the active chalcogenide material 14 to protect the chalcogenide from the environment. One suitable insulator is silicon nitride.

The active chalcogenide material 14 may have a monostable chalcogenide to form an ovonic threshold switch or a bi-stable chalcogenide to form an phase-change memory. The polycrystalline electrode may have grains of various sizes from 10 Angstroms to 500 nanometers.

The largest grain size of the electrode material may be less than the size of the electrode 12 (or electrode 16) itself in some embodiments.

Referring to FIG. 3, a plot of asymmetry coefficient versus resistivity for a p-type doped polysilicon lower electrode is illustrated. A larger asymmetry coefficient corresponds to greater asymmetry. The coefficient may be calculated by measuring the extent to which the i-v curve extends from either the zero current or the zero voltage axis in two opposite directions and taking a ratio of those distances. Notice that a region of lower resistivity exists below 5 Ohmcentimeters, wherein the asymmetry coefficient is also more stable or less variable. Thus, in some embodiments, it may be advantageous to form the lower electrode 12 with a resistivity less than about 5 Ohmcentimeters and an asymmetry coefficient of at least 1.5.

In accordance with some embodiments of the present invention, an ovonic memory cell or ovonic threshold switch may include an electrode with a doped amorphous or polycrystalline semiconductor electrode 12, does not need additional wafer real estate, and can be easily integrated into an integrated circuit.

Programming of the chalcogenide material 14 to alter the state or phase of the material may be accomplished by applying voltage potentials to the lower electrode 12 and upper electrode 16, thereby generating a voltage potential across the memory element. When the voltage potential is greater than the threshold voltages of memory element, then an electrical current may flow through the chalcogenide material 14 in response to the applied voltage potentials, and may result in heating of the chalcogenide material 14.

This heating may alter the memory state or phase of the chalcogenide material 14. Altering the phase or state of the chalcogenide material 14 may alter the electrical characteristic of memory material, e.g., the resistance of the material may be altered by altering the phase of the memory material. Memory material may also be referred to as a programmable resistive material.

In the “reset” state, memory material may be in an amorphous or semi-amorphous state and in the “set” state, memory material may be in an a crystalline or semi-crystalline state. Both “reset” and “set” states can exist without any energy (electrical, optical, mechanical) applied to bistable material 14. The resistance of memory material in the amorphous or semi-amorphous state may be greater than the resistance of memory material in the crystalline or semi-crystalline state. It is to be appreciated that the association of reset and set with amorphous and crystalline states, respectively, is a convention and that at least an opposite convention may be adopted.

Using electrical current, memory material may be heated to a relatively higher temperature to amorphosize memory material and “reset” memory material (e.g., program memory material to a logic “0” value). Heating the volume of memory material to a relatively lower crystallization temperature may crystallize memory material and “set” memory material (e.g., program memory material to a logic “1” value). Various resistances of memory material may be achieved to store information by varying the amount of current flow and duration through the volume of memory material.

A select device may operate as a switch that is either “off” or “on” depending on the amount of voltage potential applied across the cell, and more particularly whether the current through the select device exceeds its threshold current or voltage, which then triggers the device into the on state. The off state may be a substantially electrically nonconductive state and the on state may be a substantially conductive state, with less resistance than the off state.

In the on state, the voltage across the select device, in one embodiment, is equal to its holding voltage V_{H} plus I×Ron, where Ron is the dynamic resistance from the extrapolated X-axis intercept, V_{H}. For example, a select device may have threshold voltages and, if a voltage potential less than the threshold voltage of a select device is applied across the select device, then the select device may remain “off” or in a relatively high resistive state so that little or no electrical current passes through the memory cell and most of the voltage drop from selected row to selected column is across the select device. Alternatively, if a voltage potential greater than the threshold voltage of a select device is applied across the select device, then the select device may “turn on,” i.e., operate in a relatively low resistive state so that electrical current passes through the memory cell. In other words, one or more series connected select devices may be in a substantially electrically nonconductive state if less than a predetermined voltage potential, e.g., the threshold voltage, is applied across select devices. Select devices may be in a substantially conductive state if greater than the predetermined voltage potential is applied across select devices. Select devices may also be referred to as an access device, an isolation device, or a switch.

In one embodiment, each select device may comprise a switch material 14 such as, for example, a chalcogenide alloy, and may be referred to as an ovonic threshold switch, or simply a switch. The switch material 14 of select devices may be a material in a substantially amorphous state positioned between two electrodes that may be repeatedly and reversibly switched between a higher resistance “off” state (e.g., greater than about one megaOhms) and a relatively lower resistance “on” state (e.g., less than about one thousand Ohms) by application of a predetermined electrical current or voltage potential. In this embodiment, each select device may be a two terminal device that may have a current-voltage (I-V) characteristic similar to a phase change memory element that is in the amorphous state. However, unlike a phase change memory element, the monostable switching material 14 of select devices may not change phase. That is, the switching material of select devices may not be a programmable material, and, as a result, select devices may not be a memory device capable of storing information. For example, the switching material of select devices may remain permanently amorphous and the I-V characteristic may remain the same throughout the operating life.

In the low voltage or low electric field mode, i.e., where the voltage applied across select device is less than a threshold voltage (labeled V_{TH}), a select device may be “off” or nonconducting, and exhibit a relatively high resistance, e.g., greater than about 1 megaOhms. The select device may remain in the off state until a sufficient voltage, e.g., V_{TH}, is applied, or a sufficient current is applied, e.g., I_{TH} that may switch the select device to a conductive, relatively low resistance on state. After a voltage potential of greater than about V_{TH} is applied across the select device, the voltage potential across the select device may drop (“snapback”) to a holding voltage potential, V_{H}. Snapback may refer to the voltage difference between V_{TH} and V_{H} of a select device.

In the on state, the voltage potential across select device may remain close to the holding voltage of V_{H} as current passing through select device is increased. The select device may remain on until the current through the select device drops below a holding current, I_{H}. Below this value, the select device may turn off and return to a relatively high resistance, nonconductive off state until the V_{TH} and I_{TH} are exceeded again.

In some embodiments, only one select device may be used. In other embodiments, more than two select devices may be used. A single select device may have a V_{H} about equal to its threshold voltage, V_{TH}, (a voltage difference less than the threshold voltage of the memory element) to avoid triggering a reset bit when the select device triggers from a threshold voltage to a lower holding voltage called the snapback voltage. An another example, the threshold current of the memory element may be about equal to the threshold current of the access device even though its snapback voltage is greater than the memory element's reset bit threshold voltage.

One or more MOS or bipolar transistors or one or more diodes (either MOS or bipolar) may be used as the select device. If a diode is used, the bit may be selected by lowering the row line from a higher deselect level. As a further non-limiting example, if an n-channel MOS transistor is used as a select device with its source, for example, at ground, the row line may be raised to select the memory element connected between the drain of the MOS transistor and the column line. When a single MOS or single bipolar transistor is used as the select device, a control voltage level may be used on a “row line” to turn the select device on and off to access the memory element.

Turning to FIG. 4, a portion of a system 500 in accordance with an embodiment of the present invention is described. System 500 may be used in wireless devices such as, for example, a personal digital assistant (PDA), a laptop or portable computer with wireless capability, a web tablet, a wireless telephone, a pager, an instant messaging device, a digital music player, a digital camera, or other devices that may be adapted to transmit and/or receive information wirelessly. System 500 may be used in any of the following systems: a wireless local area network (WLAN) system, a wireless personal area network (WPAN) system, a cellular network, although the scope of the present invention is not limited in this respect.

System 500 may include a controller 510, an input/output (I/O) device 520 (e.g. a keypad, display), static random access memory (SRAM) 560, a memory 530, and a wireless interface 540 coupled to each other via a bus 550. A battery 580 may be used in some embodiments. It should be noted that the scope of the present invention is not limited to embodiments having any or all of these components.

Controller 510 may comprise, for example, one or more microprocessors, digital signal processors, microcontrollers, or the like. Memory 530 may be used to store messages transmitted to or by system 500. Memory 530 may also optionally be used to store instructions that are executed by controller 510 during the operation of system 500, and may be used to store user data. Memory 530 may be provided by one or more different types of memory. For example, memory 530 may comprise any type of random access memory, a volatile memory, a non-volatile memory such as a flash memory and/or a memory such as memory discussed herein.

I/O device 520 may be used by a user to generate a message. System 500 may use wireless interface 540 to transmit and receive messages to and from a wireless communication network with a radio frequency (RF) signal. Examples of wireless interface 540 may include an antenna or a wireless transceiver, although the scope of the present invention is not limited in this respect.

References throughout this specification to “one embodiment” or “an embodiment” mean that a particular feature, structure, or characteristic described in connection with the embodiment is included in at least one implementation encompassed within the present invention. Thus, appearances of the phrase “one embodiment” or “in an embodiment” are not necessarily referring to the same embodiment. Furthermore, the particular features, structures, or characteristics may be instituted in other suitable forms other than the particular embodiment illustrated and all such forms may be encompassed within the claims of the present application.

While the present invention has been described with respect to a limited number of embodiments, those skilled in the art will appreciate numerous modifications and variations therefrom. It is intended that the appended claims cover all such modifications and variations as fall within the true spirit and scope of this present invention.

1. A method comprising:
forming a chalcogenide device with an asymmetry coefficient of greater than 1.5.

2. The method of claim 1 including forming a phase change memory, including a pair of spaced electrodes and a chalcogenide alloy between said electrodes, with a bistable asymmetric current-voltage curve.

3. The method of claim 2 including forming one of said electrodes of doped amorphous or polycrystalline semiconductor.

4. The method of claim 1 including forming an ovonic threshold switch with a monostable asymmetric current-voltage curve.

5. The method of claim 1 including forming an ovonic memory with an asymmetric i-v curve.

6. (canceled)

7. The method of claim 2 including forming a lower of said electrodes to have less than 5 Ohmcentimeter resistivity.

8. The method of claim 1 including forming said device with electrodes that sandwich a chalcogenide material, one of said electrodes being polysilicon having a grain size of from 10 Angstroms to 500 nanometers.

9. The method of claim 1 including forming said device with an asymmetry coefficient of greater than 1.5.

10. A memory comprising:
a chalcogenide material;
a pair of electrodes sandwiching said chalcogenide material; and
one of said electrodes being polysilicon having a grain size of from 10 Angstroms to 500 nanometers.

11. The memory of claim 10 wherein one of said electrodes is formed of doped amorphous or polycrystalline semiconductor.

12. The memory of claim 10 wherein said device has an asymmetry coefficient of greater than 1.5.

13. The memory of claim 10 wherein the lower of said electrodes has a resistivity of less than 5 Ohmcentimeters.

14. The memory of claim 10 wherein said chalcogenide material forms an ovonic threshold switch.

15. The memory of claim 10 wherein said chalcogenide material forms an ovonic memory.

16. (canceled)

17. A memory comprising:
a chalcogenide material;
a pair of electrodes around said chalcogenide material; and
said memory having an asymmetry coefficient of greater than 1.5.

18. The memory of claim 17 wherein the lower of said electrodes is formed of doped amorphous or polycrystalline semiconductor.

19. (canceled)

20. The memory of claim 17 wherein said chalcogenide material forms an ovonic threshold switch.

21. The memory of claim 17 wherein said chalcogenide material forms an ovonic memory.

22. A system comprising:
a processor;
a static random access memory coupled to said processor; and
a phase change memory coupled to said processor, said phase change memory including a chalcogenide material, a pair of electrodes around said chalcogenide material, and said phase change memory having an asymmetry coefficient of greater than 1.5.

23. The system of claim 22 wherein said memory is an ovonic threshold switch.

24. The system of claim 22 wherein said memory is an ovonic memory.

25. The system of claim 22 wherein the lower of said electrodes is formed of doped amorphous or polycrystalline semiconductor.
